(19) United States
(12) Patent Application Publication
(10) Pub. No.: US 2011/0094579 A1
(43) Pub. Date: Apr. 28, 2011

(54) Electrode substrate, method of preparing same, and photoelectric conversion device including same

(76) Inventors: Yukika Yamada, Yokohama (JP); Tadao Yagi, Yokohama (JP); Yoshitaka Terao, Yokohama (JP); Jong-Ki Lee, Yongin-si (KR); Nam-Choul Yang, Yongin-si (KR); Hyun-Chul Kim, Yongin-si (KR); Jung-Tae Park, Yongin-si (KR)

(21) Appl. No.: 12/925,614

(22) Filed: Oct. 25, 2010

(30) Foreign Application Priority Data
Oct. 26, 2009 (JP) 2009-245916
May 31, 2010 (KR) 10-2010-0051311

(51) Int. Cl. H01L 31/0224; H01L 31/18

(52) U.S. Cl. 136/256; 438/98; 257/E31.124

(57) ABSTRACT

An electrode substrate for a photoelectric conversion device includes a current-collecting electrode on a transparent conductive substrate and a coating film coating a surface of the current-collecting electrode substrate, wherein the coating film is formed by coating the surface of the current-collecting electrode with a glass paste composition and baking the current-collecting electrode coated with the glass paste composition, and when a thickness of the coating film is a μm and a maximal length of a pore in the coating film is b μm, a condition of b≦0.5a is satisfied.

### CROSS-REFERENCE TO RELATED APPLICATIONS

This application claims priority to and the benefit of Japanese Patent Application No. 2009-245916 filed in the Japanese Patent Office on Oct. 26, 2009, and Korean Patent Application No. 10-2010-0051311 filed in the Korean Intellectual Property Office on May 31, 2010, the entire contents of which are incorporated herein by reference.

### BACKGROUND

1. Field

This disclosure relates to an electrode substrate, a method of fabricating the same, and a photoelectric conversion device including the same.

2. Description of the Related Art

Studies on photoelectric conversion devices such as solar cells for converting photo energy into electrical energy have been actively performed to provide clean energy having little environmental impact.

The solar cells include, for example, a silicon-based solar cell such as a monocrystalline silicon solar cell, a polysilicon solar cell, an amorphous silicon solar cell or the like; or a compound semiconductor solar cell using a compound semiconductor such as cadmium telluride, copper indium selenide, or the like instead of silicon.

However, the solar cells typically have problems such as high cost, rare raw materials, and prolonged energy recycle time.

On the other hand, although solar cells using an organic material aiming for large area application at a low cost have been suggested, the conversion efficiency or the durability thereof are still insufficient.

A dye sensitized solar cell using a semiconductor porous body sensitized by a dye has been developed. For example, a dye sensitized solar cell (e.g., Gratzel cell) in which a dye is fixed on the surface of a porous titanium oxide thin film has been researched and developed.

The Gratzel cell is a dye-sensitized photoelectric conversion cell including a working electrode of a titanium oxide porous thin film layer spectral-sensitized by a ruthenium complex dye, an electrolyte layer including a main component of urea, and a counter electrode.

The Gratzel cell has characteristics as follows: it can provide an inexpensive photoelectric conversion device since it includes an inexpensive oxide semiconductor such as titanium oxide; and it may provide relatively high conversion efficiency since the ruthenium complex dye adsorbs a wide visible ray region.

The dye sensitized solar cell is reported to have conversion efficiency over 12%, so it has sufficient practicality as compared to a silicon-based solar cell.

Generally, when a photoelectric conversion device such as a solar cell is enlarged, the photoelectric conversion efficiency may be deteriorated since the generated current is converted into Joule heat in a low-conductive substrate such as a transparent electrode.

In order to overcome the problem, attempts have been made to form a highly conductive metal line such as silver and copper to provide a current-collecting electrode (grid electrode), so as to decrease the electrical energy loss in a solar cell.

When the current-collecting electrode is provided in a dye sensitized solar cell, it is necessary to prevent or protect the current-collecting electrode from being corroded by an electrolyte solution including urea.

It has also been suggested that the circumference of the current-collecting electrode should be coated or protected with a glass material having a low melting point.

For example, a plurality of coating films are on a current-collecting electrode, or a current-collecting electrode is made from a material having excellent resistance to an electrolyte solution without a coating film.

In addition, it has also been suggested to use materials, such as the glass material, for a coating film coating the current-collecting electrode to have a coefficient of linear expansion that is similar to the substrate to prevent or protect from cracking of the coating film.

However, in a typical solar cell, sufficient electrolyte solution resistance may not be provided.

The typical solar cell has a complicated structure, and the typical solar cell has reduced performance since a material having excellent electrolyte solution resistance usually has high resistance.

In the typical solar cell, a coating film is also stressed after baking the glass material of the coating film, thereby causing cracks.

As described above, the related arts do not effectively prevent or protect from cracks of coating films.

### SUMMARY

An aspect of an embodiment of the present invention is directed toward an electrode substrate for a photoelectric conversion device that can prevent or protect a coating film coating a current-collecting electrode from generating cracks and provide sufficient electrolyte solution resistance.

Another aspect of an embodiment of the present invention is directed toward a photoelectric conversion device including the electrode substrate for a photoelectric conversion device.

Yet another aspect of an embodiment of the present invention is directed toward a method of fabricating the electrode substrate.

According to an embodiment of this disclosure, an electrode substrate for a photoelectric conversion device includes a transparent conductive substrate, a current-collecting electrode on the transparent conductive substrate, and a coating film coating a surface of the current-collecting electrode, wherein when a thickness of the coating film is a and a maximal length of a pore is b, a condition of b≦0.5a is satisfied.

The coating film may be formed by coating the surface of the current-collecting electrode with a glass paste composition and baking the current-collecting electrode coated with the glass paste composition.

According to another embodiment of this disclosure, an electrode substrate for a photoelectric conversion device includes a transparent conductive substrate, a current-collecting electrode on the transparent conductive substrate, and a coating film coating a surface of the current-collecting electrode, wherein a maximal length of a pore is not longer than 10 μm or about 10 μm. The coating film may be formed by coating the surface of the current-collecting electrode with a glass paste composition and baking the current-collecting electrode coated with the glass paste composition.

According to another embodiment of this disclosure, a photoelectric conversion device includes the electrode substrate.

The photoelectric conversion device may be a dye sensitized solar cell.

According to another embodiment of this disclosure, a method for fabricating an electrode substrate includes: forming a coating film coating a surface of a current-collecting electrode on a transparent conductive substrate with a glass paste composition including a glass frit, a binder resin, and an organic solvent; and baking the glass paste composition at a baking temperature equal to or higher than a softening temperature (Ts) of the glass frit and lower than a temperature of 40° C. or about 40° C. higher than the softening temperature (Ts+40° C.).

The method may further include maintaining the glass paste composition at a temperature not lower than a vanishing temperature of the binder resin and not higher than the softening temperature (Ts) of the glass frit for more than or equal to 5 minutes or about 5 minutes, before reaching the baking temperature.

According to one or more embodiments of this disclosure, in an electrode substrate for a photoelectric conversion device including a current-collecting electrode, a fabrication method thereof, and a photoelectric conversion device including the electrode substrate, a coating film coating a current-collecting electrode may be protected from cracking and sufficient electrolyte solution resistance may be obtained by controlling a maximal length of a pore generated in the coating film though baking of a glass paste composition at less than or equal to about half a thickness of the coating film, or less than or equal to 10 μm or about 10 μm.

Accordingly, the photoelectric conversion device including the electrode substrate can exhibit high efficiency and a long lifespan.

### BRIEF DESCRIPTION OF THE DRAWINGS

FIG. 1 is a diagram showing a structure of a photoelectric conversion device according to an embodiment.

FIG. 2 is a diagram schematically showing the operations between an inorganic metal oxide semiconductor and a dye.

FIG. 3 is a diagram showing a structure of an electrode substrate according to an embodiment.

FIGS. 4A and 4B are diagrams showing a structure of a coating film on the electrode substrate shown in FIG. 3.

FIG. 5 is a graph showing a baking profile of a glass paste composition according to an embodiment.

FIG. 6A is a microscope photograph exemplarily showing a state of a coating film after being baked.

FIG. 6B is a microscope photograph exemplarily showing a state of a coating film after being baked.

FIG. 6C is a microscope photograph exemplarily showing a state of a coating film after being baked.

FIG. 6D is a microscope photograph exemplarily showing a state of a coating film after being baked.

FIG. 6E is a microscope photograph exemplarily showing a state of a coating film after being baked.

FIG. 6F is a microscope photograph exemplarily showing a state of a coating film after being baked.

FIG. 7A is a microscope photograph exemplarily showing a state of a coating film after being baked, when a pre-process is not applied.

FIG. 7B is a microscope photograph exemplarily showing a state of a coating film after being baked, when a pre-process is applied.

FIG. 8A is a microscope photograph exemplarily showing a state of a corroded current-collecting electrode.

FIG. 8B is a microscope photograph exemplarily showing a state of a corroded current-collecting electrode.

FIG. 9 is a graph showing relationships between the conversion efficiencies (η) of photoelectric conversion cells versus time according to an example and a comparative example.

### DETAILED DESCRIPTION

Exemplary embodiments of the present invention will hereinafter be described in detail. However, these embodiments are only exemplary, and the present invention is not limited thereto.

In the present specification and drawings, constituent elements having substantially equivalent functions are designated the same number, and repeating descriptions are not provided.

When a glass material is used to form a coating film, the glass may crack due to a difference in the coefficient of linear expansion between the glass material and a substrate, and pores may be generated in the coating film when the glass material is baked.

In other words, after the baking of the glass material, the coating film may crack due to pores existing in the coating film according to the size of the pores, when a photoelectric conversion device such as a solar cell is manufactured.

According to embodiments of the present invention, the coating film may be protected from cracking by controlling the size of the pores generated in the coating film when the glass material is baked.

### Embodiment 1

### Structure of Photoelectric Conversion Device

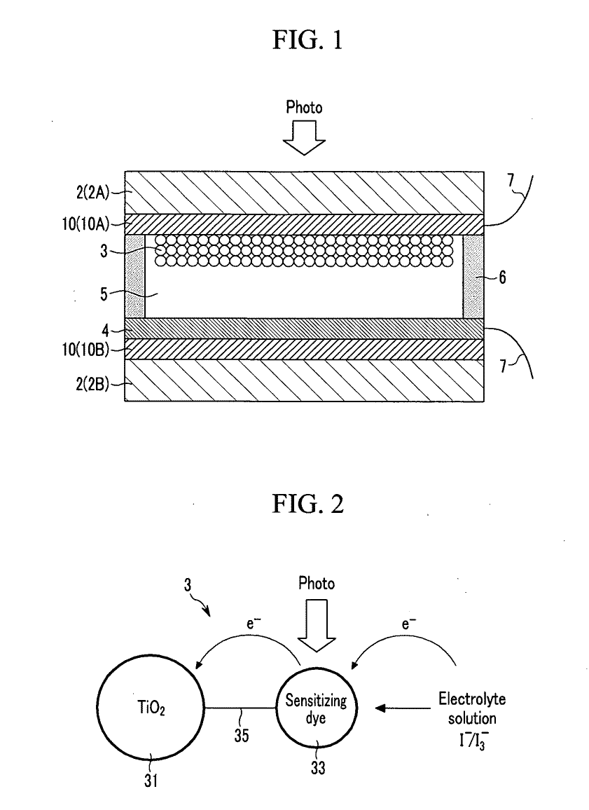

First, the structure of a photoelectric conversion device according to one embodiment is described with reference to FIG. 1 and FIG. 2.

FIG. 1 is a diagram illustrating the structure of a photoelectric conversion device 1 according to an embodiment.

FIG. 2 is a diagram schematically illustrating operations between the inorganic metal oxide semiconductor and the dye.

Hereinafter, the photoelectric conversion device 1 including a Gratzel cell shown in FIG. 1 is described as an example.

As shown in FIG. 1, the photoelectric conversion device 1 according to one embodiment includes two substrates 2, two electrode substrates 10, a photoelectrode 3, a counter electrode 4, an electrolyte solution 5, a spacer 6, and lead wires 7.

### Substrate

The two substrates 2 face each other while leaving a gap (e.g., a predetermined gap) therebetween.

The material for the substrates 2 is not specifically limited as long as it is a suitable transparent material that is transmissive to light from the visible ray region to the near infrared ray region (e.g., solar light, etc.) incident upon the photoelectric conversion device 1.

The material of the substrates 2 may include, for example, a glass such as quartz, common glass, BK7, lead glass, or the like, or a resin such as polyethylene terephthalate, polyethylene naphthalate, polyimide, polyester, polyethylene, polycarbonate, polyvinylbutyrate, polypropylene, tetra acetyl cellulose, syndiotactic polystyrene, polyphenylene sulfide, polyarylate, polysulfone, polyester sulfone, polyetherimide, cyclic polyolefin, phenoxy bromide, vinyl chloride, or the like.

### Electrode Substrate

At least one of the electrode substrates 10 (10A and 10B) is formed on the surface of the substrate 2A that is located at a light incident side of the two substrates 2, and it includes, for example, a transparent electrode including a transparent conductive oxide (TCO). The transparent electrode will be described in more detail below.

In order to improve photoelectric conversion efficiency, the sheet resistance (surface resistance) of the electrode substrate 10 needs to be decreased as much as possible, for example, to 20 Ω/cm² (Ω/sq.) or less.

In one embodiment, the electrode substrate 10B may not be provided on the surface of the substrate 2B facing the substrate 2A, and it may not be transparent (i.e., less light transmission in the region from the visible ray region to the near infrared ray region of light incident upon the photoelectric conversion device 1 when the electrode substrate 10B is provided.

The electrode substrate 10 according to one embodiment will now be described in more detail below.

### Photoelectrode

In the photoelectric conversion device 1, according to one embodiment, the photoelectrode 3 includes an inorganic metal oxide semiconductor layer having a photoconversion function, and is formed with a porous layer.

For example, as shown in FIG. 1, the photoelectrode 3 is formed by laminating a particulate 31 of an inorganic metal oxide semiconductor (hereinafter referred to as “metal oxide particulate 31”) of a plurality of TiO₂ particles or the like, which is a porous body (e.g., nanoporous layer) including nanometer-sized pores in the laminated metal oxide particulate 31, on the surface of the electrode substrate 10.

Since the photoelectrode 3 is formed with a porous body including a plurality of small pores, the surface area of the photoelectrode 3 is increased, and a large amount of sensitizing dye 33 is applied to the surface of the metal oxide particulate 31. Thereby, the photoelectric conversion device 1 may have high photoelectric conversion efficiency.

As shown in FIG. 2, the sensitizing dye 33 is connected to the surface of the metal oxide particulate 31 through a connecting group 35 to provide a photoelectrode 3 of which the inorganic metal oxide semiconductor is sensitized.

The term “connection” indicates that the inorganic metal oxide semiconductor is chemically and physically bound with the sensitizing dye (for example, binding by adsorption or the like).

Accordingly, the term “connecting group” indicates inclusion of an anchor group or an adsorbing group as well as a chemical functional group.

Although FIG. 2 shows that one sensitizing dye 33 unit is connected to the surface of the metal oxide particulate 31, this is only for ease of explanation. In order to improve the electrical output of photoelectric conversion device 1, the number of sensitizing dye 33 units connected to the surface of the metal oxide particulate 31 is increased as much as practicably possible, and a plurality of sensitizing dye 33 units are applied on the surface of the metal oxide particulate 31 as wide as practicably possible.

When the number of sensitizing dye 33 units is increased, excited electrons are recombined due to interaction between adjacent sensitizing dyes 33 units, and it becomes very difficult to output the electrical energy, so a co-adsorption material such as deoxycholic acid may be used to maintain an appropriate distance and to coat the sensitizing dye 33 units.

The photoelectrode 3 may be formed by laminating metal oxide particulates 31 of which a primary particle has an average particle diameter of about 20 μm to about 100 μm in a plurality of layers.

The photoelectrode 3 has a layer thickness of several microns (in some embodiments, 10 μm or less).

In one embodiment, when the photoelectrode 3 has a layer thickness of less than several microns, light transmitted through the photoelectrode 3 is increased and/or the sensitizing dye 33 is insufficiently excited, such that desired photoelectric conversion efficiency may not be obtained.

On the other hand, in one embodiment, when the photoelectrode 3 has a layer thickness of more than several microns, the distance between the surface of the photoelectrode 3 (surface of a side contacting the electrolyte solution 5) and the electric conductive surface (interface between the photoelectrode 3 and the electrode substrate 10) is increased, so it is difficult to effectively transmit generated excited electrons to the electric conductive surface. Therefore, it may not provide good conversion efficiency.

The metal oxide particulate 31 and the sensitizing dye 33 for a photoelectrode 3 according to one embodiment will now be described in more detail below.

### Metal Oxide Particulate

The inorganic metal oxide semiconductor generally has a photoelectric conversion function with regard to light in a certain wavelength region, but it is possible to photoelectrically convert the light in the region from the visible ray to the near infrared ray by connecting the sensitizing dye 33 to the surface of the metal oxide particulate 31.

The compound for a metal oxide particulate 31 is not specifically limited as long as it enhances the photoelectric conversion function by being connected with the sensitizing dye 33. In some embodiments, it may include, for example, titanium oxide, tin oxide, tungsten oxide, zinc oxide, indium oxide, niobium oxide, iron oxide, nickel oxide, cobalt oxide, strontium oxide, tantalum oxide, antimony oxide, oxides of lanthanide, yttrium oxide, vanadium oxide, or the like.

As the surface of the metal oxide particulate 31 is sensitized by the sensitizing dye 33, the conduction band of the inorganic metal oxide can easily receive electrons from a photo-excitation trap of the sensitizing dye 33.

In some embodiments, the compound for a metal oxide particulate 31 may include, for example, titanium oxide, tin oxide, zinc oxide, niobium oxide, or the like.

In addition, it may include titanium oxide in view of cost and environmental consideration.

According to one embodiment, the metal oxide particulate 31 may include a single kind of the inorganic metal oxide or an assembly of multiple kinds thereof.

### Sensitizing Dye

The sensitizing dye 33 is not specifically limited as long as the metal oxide particulate 31 photoelectrically converts the light in a region previously having no substantial photoelectric conversion function (for example, from the visible ray to the near infrared ray region), but it may include, for example, an azo-based dye, a quinacridone-based dye, a diketopyrrolopyrrole-based dye, a squarylium-based dye, a cyanine-based dye, a merocyanine-based dye, a triphenylmethane-based dye, a xanthene-based dye, a porphyrin-based dye, a chlorophyll-based dye, a ruthenium complex-based dye, an indigo-based dye, a perylene-based dye, a dioxadine-based dye, an anthraquinone-based dye, a phthalocyanine-based dye, a naphthalocyanine-based dye, and derivatives thereof, or the like.

The sensitizing dye 33 may include a connecting group 35 of a functional group capable of connecting to the surface of the metal oxide particulate 31 in order to effectively transmit the excited electrons of the photo-excited dye into the conductive band of the inorganic metal oxide.

The functional group is not specifically limited as long as it is a suitable substituent connecting the sensitizing dye 33 to the surface of the metal oxide particulate 31 and effectively transmitting the excited electrons of the dye to the conductive band of the inorganic metal oxide. In some embodiments, it may include, for example, a carboxyl group, a hydroxyl group, a hydroxamic acid group, a sulfonic acid group, a phosphonic acid group, a phosphinic acid group, or the like.

### Counter Electrode

The counter electrode 4 may be a positive electrode of the photoelectric conversion device 1, and it is a film on the surface of the substrate 2B facing the substrate 2A on which the electrode substrate 10A is formed to face the electrode substrate 10B.

In other words, the counter electrode 4 is on the surface of the electrode substrate 10B to face the photoelectrode 3 in the region surrounded by the two electrode substrates 10 and the spacer 6.

A metal catalyst layer having conductivity is on the surface of the counter electrode 4 on the side facing the photoelectrode 3.

A conductive material for the metal catalyst layer of the counter electrode 4 may include, for example, a metal (platinum, gold, silver, copper, aluminum, rhodium, indium, or the like), a metal oxide (indium tin oxide (ITO), tin oxide (including one doped with fluorine or the like), zinc oxide, or the like), a conductive carbon material or a conductive organic material, or the like.

The layer thickness of the counter electrode 4 is not specifically limited, but it may range, for example, from about 5 μm to about 10 μm.

On the other hand, lead wires 7 are respectively coupled to the electrode substrate 10A that is formed with the photoelectrode 3 and the counter electrode 4, so the lead wire 7 from the electrode substrate 10A and the lead wire 7 from the counter electrode 4 are coupled to one or more components outside of the photoelectric conversion device 1 to complete a current circuit.

In addition, the electrode substrate 10A and the counter electrode 4 are separated by a spacer 6 to leave a gap (e.g., a predetermined gap) therebetween.

The spacer 6 is formed along the perimeter (e.g., circumference) of the electrode substrate 10A and the counter electrode 4, and the spacer 6 seals the space between the electrode substrate 10A and the counter electrode 4.

The spacer 6 may be made of a resin having a high sealing property and high corrosion resistance. For example, it may include a thermoplastic resin, a photocurable resin, an ionomer resin, a glass frit, or the like.

The ionomer resin may include, for example, HIMILAN (trade name) produced by Mitsui DuPont Polychemical K.K, or the like.

### Electrolyte Solution

The electrolyte solution 5 is injected into the space between the electrode substrate 10A and the counter electrode 4, and it is sealed therein with the spacer 6.

The electrolyte solution 5 may include, for example, an electrolyte, a medium, or additives.

The electrolyte may include a redox electrolyte such as an I₃⁻/I⁻-based and a Br₃⁻/Br⁻-based electrolyte, and, in some embodiments, it may include, for example, a mixture of I₂ and an iodide (LiI, NaI, KI, CsI, MgI₂, CaI₂, CuI, tetraalkylammonium iodide, pyridinium iodide, imidazolium iodide, or the like), a mixture of Br₂ and bromide (LiBr etc.), an organic molten salt compound, or the like, but it is not limited thereto.

The organic molten salt compound is a compound including organic cations and inorganic or organic anions, and has a melting point of room temperature or less.

The organic cations for an organic molten salt compound may include aromatic cations. In some embodiments, it may include, for example, N-alkyl-N′-alkylimidazolium cations such as N-methyl-N′-ethylimidazolium cations, N-methyl-N′-n-propylimidazolium cations, N-methyl-N′-n-hexylimidazolium cations, or the like, or N-n alkylpyridinium cations such as N-hexylpyridinium cations, N-butylpyridinium cations, or the like.

In addition, the aliphatic cations may include aliphatic cations such as N,N,N-trimethyl-N-propylammonium cations or the like, or cyclic aliphatic cations such as N,N-methylpyrrolidinium cations or the like.

The inorganic or organic anions for an organic molten salt compound may include, for example, halide ions such as chloride ions, bromide ions, iodide ions, or the like; inorganic anions such as phosphorus hexafluoride ions, boron tetrafluoride ions, methane sulphonic trifluoride ions, perchloric acid ions, hypochloric acid ions, chloric acid ions, sulfonic acid ions, phosphoric acid ions, or the like; or amide anions or imide anions such as bis(trifluoromethylsulfonyl)imide anions or the like.

The organic molten salt compound may be a suitable known compound.

The above mentioned iodide, bromide, or the like may be applied singularly or in combination of one or more kinds thereof.

In one embodiment, the electrolyte may be a mixture of I₂ and iodide (for example, I₂ and LiI, pyridinium iodide, imidazolium iodide, or the like) are mixed, but it is not limited thereto.

The electrolyte solution 5 may have a concentration including I₂ at about 0.01 M to about 0.5 M, and iodide and/or bromide (a mixture thereof in the case of both) at about 0.1 M to about 15 M.

The medium for the electrolyte solution 5 may be a suitable compound providing excellent ion conductivity.

In some embodiments, the liquid medium may include, for example, ether compounds such as dioxane, diethylether, or the like; linear ethers such as ethylene glycol dialkylether, propylene glycol dialkylether, polyethylene glycol dialkylether, polypropylene glycol dialkylether, or the like; alcohols such as methanol, ethanol, ethylene glycol monoalkylether, propylene glycol monoalkylether, polyethylene glycol monoalkylether, polypropylene glycol monoalkylether, or the like; polyhydric alcohols such as ethylene glycol, propylene glycol, polyethylene glycol, polypropylene glycol, glycerine, or the like; nitrile compounds such as acetonitrile, glutarodinitrile, methoxy acetonitrile, propionitrile, benzonitrile, or the like; carbonate compounds such as ethylene carbonate, propylene carbonate, or the like; heterocyclic ring compounds such as 3-methyl-2-oxazolidinone or the like; aprotic polar materials such as dimethyl sulfoxide, sulfolanes, or the like; water; or the like.

The above listed materials for the liquid medium may be applied singularly or in a combination of one or more thereof.

To provide a solid (including a gel) medium, a polymer may be added to the liquid medium.

In some embodiments, a polymer such as polyacrylonitrile, polyvinylidene fluoride, or the like is added to the liquid medium, or a multi-functional monomer including an ethylenic unsaturated group is polymerized in the liquid medium to provide a solid medium.

The medium that may be used for the electrolyte solution 5 may include an organic-inorganic ion pair (also referred to as an ionic liquid) that becomes a liquid at room temperature.

When the ionic liquid is used as the medium for the electrolyte solution 5, it may suppress evaporation thereof. Thus, the durability of the photoelectric conversion device 1 may be improved.

The electrolyte solution 5 may also include a hole transport material such as CuI, CuSCN (these compounds are P-type semiconductors not requiring a liquid medium and act as an electrolyte), or other suitable hole transferring materials such as 2,2′,7,7′-tetrakis(N,N-di-p-methoxyphenylamine)-9,9′-spirobifluorene or the like.

Other suitable additives may be further added to the electrolyte solution 5 in order to improve the durability of the photoelectric conversion device 1 or the electrical output.

For example, inorganic salts such as magnesium iodide or the like may be added in order to improve durability. Amines such as t-butyl pyridine, 2-picoline, 2,6-lutidine, or the like; steroids such as deoxycholic acid or the like, monosaccharides or sugar alcohols such as glucose, glucosamine, glucuronic acid, or the like; disaccharides such as maltose or the like; linear oligosaccharides such as raffinose or the like; cyclic oligosaccharides such as cyclodextrin or the like; or hydrolysis oligosaccharides such as lacto oligosaccharide or the like may be added in order to improve the electrical output.

In addition, the thickness of the layer injected with the electrolyte solution 5 and sealed is not specifically limited, but the thickness is determined to prevent or protect from direct contact between the counter electrode 4 and the photoelectrode 3 adsorbed with the dye.

For example, the thickness may range from about 0.1 μm to about 100 μm.

### Working Principle of Photoelectric Conversion Device

In the photoelectrode 3 including a metal oxide particulate 31 and a sensitizing dye 33 connected to the surface of the metal oxide particulate 31 through a connecting group 35, the sensitizing dye 33 is excited to release excited electrons when light is incident upon the sensitizing dye 33 connected to the surface of the metal oxide particulate 31, as shown in FIG. 2.

The released excited electrons are transmitted to the conductive band of the metal oxide particulate 31 through the connecting group 35.

The excited electrons travel from the metal oxide particulate 31 to another metal oxide particulate 31 and reach the electrode substrate 10, and the excited electrons travel to the outside of the photoelectric conversion device 1 through the lead wire 7.

On the other hand, the sensitizing dye 33 (that loses the excited electrons) receives electrons supplied from the counter electrode 4 through the electrolyte such as I⁻/I₃⁻ or the like in the electrolyte solution 5, so it returns to an electrically neutral state.

### Electrode Substrate 10

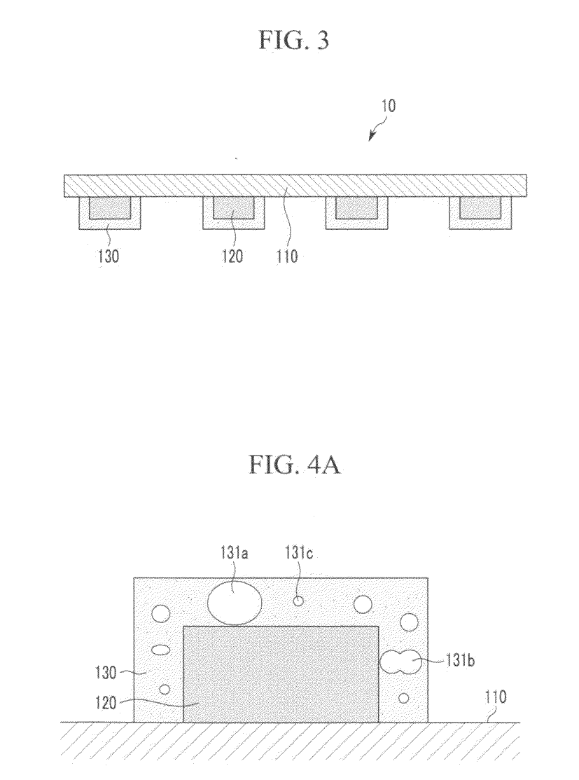

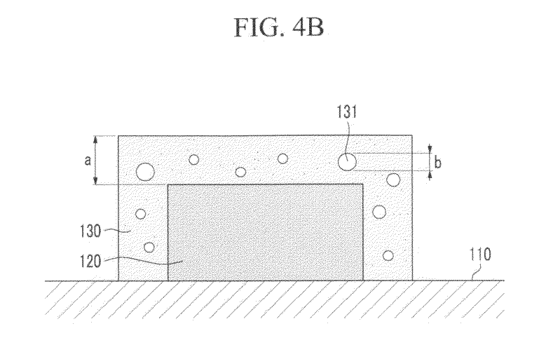

The structure of the photoelectric conversion device 1 according to one embodiment is described above, and hereinafter, the constitution of the electrode substrate 10 according to one embodiment will be described in more detail below referring to FIG. 3, FIG. 4A, and FIG. 4B.

FIG. 3 is a diagram showing a structure of the electrode substrate 10 according to one embodiment.

FIGS. 4A and 4B are diagrams showing the structure of the coating film formed on the electrode substrate 10 shown in FIG. 3.

As shown in FIG. 3, the electrode substrate 10 according to one embodiment includes a transparent electrode 110, a current-collecting electrode 120, and a coating film 130 as one example.

The transparent electrode 110 is formed in a layer using, for example, a transparent conductive oxide (TCO).

The TCO is not specifically limited as long as it is a suitable conductive material that is transmissive to light in the region from the visible ray to the infrared ray of the light incident upon the photoelectric conversion device 1. In some embodiments, the TCO may include a metal oxide having good conductivity such as indium tin oxide (ITO), tin oxide (SnO₂), fluorine-doped tin oxide (FTO), antimony-included tin oxide (ITO/ATO), zinc oxide (ZnO₂), or the like.

The current-collecting electrode 120 plays a role of transmitting excited electrons having arrived in the electrode substrate 10 through the metal oxide particulate 31 to the lead wire 7, and, according to one embodiment, the current-collecting electrode 120 is a metal line on the surface of the electrode substrate 10.

The current-collecting electrode 120 has a relatively low sheet resistance (in one embodiment, about 10 Ω/sq or more), so that it prevents or reduces the generated current from being converted into joule heat in a substrate having relatively low conductivity such as the transparent electrode 110 that can deteriorate the photoelectric conversion efficiency.

In this regard, the current-collecting electrode 120 is electrically coupled to the electrode substrate 10, and, in some embodiments, the material for forming the current-collecting electrode 120 may include a highly conductive metal or alloy such as Ag, Ag/Pd, Cu, Au, Ni, Ti, Co, Cr, Al, or the like.

The wire pattern of the current-collecting electrode 120 is not specifically limited as long as the shape decreases the electrical energy loss. In some embodiments, it may be formed in a set or predetermined shape such as a lattice shape, a stripe shape, a rectangular shape, a comb tooth shape, or the like.

When the current-collecting electrode 120 is formed of a metal such as Ag, Ag/Pd, Cu, Au, Ni, Ti, Co, Cr, Al, or the like, it may be corroded by the electrolyte solution 5 including iodine (e.g., I⁻/I₃⁻ or the like).

Therefore, the photoelectric conversion device 1 according to one embodiment includes the coating film 130.

The coating film 130 acts to prevent or suppress corrosion of the current-collecting electrode 120 due to the electrolyte solution 5, and it is a layer for coating around the current-collecting electrode 120 and protecting the current-collecting electrode 120 from corrosion by the electrolyte solution 5. In one embodiment, the coating film 130 is obtained by coating a glass paste composition having a low melting point on the surface of the current-collecting electrode 120 and baking the same.

In some embodiments, the glass paste composition for the coating film 130 is a paste composition including a glass frit, a binder resin, a solvent, and an additive.

Hereinafter, each component of the glass paste composition is described in more detail.

The glass frit for a glass paste composition according to one embodiment may include a SiO₂ skeleton, a B₂O₃ skeleton, or a P₂O₅ skeleton and other metal oxides in order to control the melting point and to provide chemical stability. For example, it may include a low melting point glass of a SiO₂—Bi₂O₃-MOₓ base, a B₂O₃—Bi₂O₃-MOₓ base, a SiO₂—CaO—Na(K)₂O-MO base, a P₂O₅—MgO-MOₓ base (M is at least one kind of metal element), or the like, either singularly or in a combination of two or more kinds thereof.

The binder resin that may be used for the glass paste composition according to one embodiment of this disclosure may include a substance that is completely or substantially combusted at a temperature not higher than about 600° C. and does not leave any substantial residue, such as ethyl cellulose (EC) resin.

Also, according to another embodiment, the binder resin that may be used for the glass paste composition may include polyvinyl alcohol, polyethylene glycol, an acrylic resin, and/or a methacrylic resin.

The solvent suitable for the glass paste composition according to one embodiment of this disclosure is not limited to particular solvents.

During the manufacturing process of the photoelectric conversion device 1, the suitable solvent reduces an excessively fast drying speed that causes the glass paste composition to dry and solidify, which is undesirable.

In this regard, the solvent used for the glass paste composition according to one embodiment of this disclosure may have a boiling point higher than or equal to about 150° C. According to another embodiment, the solvent has a boiling point higher than or equal to about 180° C. Non-limiting examples of the solvent may include a terpene-based solvent (e.g., terpineol, etc.) or a carbitol-based solvent (e.g., butylcarbitol, butylcarbitol acetate, etc.).

If needed, glass frit or a suitable additive for improving the dispersion property of a resin or adjusting the rheological property of the resin may be added to the glass paste composition according to one embodiment.

The additive may include a polymer for properly adjusting the viscosity for a process such as screen printing or improving the dispersion property of glass frit, an agent for increasing viscosity for adjusting rheologcial property, and/or a dispersing agent for preparing a glass paste composition with an excellent dispersion property.

Non-limiting examples of the polymer may include polyvinyl alcohol, polyethylene glycol, ethyl cellulose (EC), acrylic resin, and/or methacrylic resin.

Non-limiting examples of the agent for increasing viscosity may include cellulose-based resins (e.g., ethyl cellulose) and/or a polyoxy alkylene resin (e.g., polyethylene glycol).

Also, non-limiting examples of the dispersing agent may include acids, e.g., a nitric acid, acetyl acetone, polyethylene glycol, and/or Triton X-100.

As to the electrode substrate 10 according to one embodiment, when the coating film 130 coating the current-collecting electrode 120 is obtained by baking a low melting point glass paste composition, the binder resin may remain in the glass paste composition during the baking process, and the remained binder resin is combusted during the baking process to be gasified in the coating film 130, so the gas present in the coating film 130 causes pores 131 as shown in FIG. 4A and FIG. 4B.

The pores 131 have a variety of shapes or sizes such as a large-sized pore 131a resulting from the generation of large-volume gas, a large-sized pore 131b agglomerated from a plurality of small-sized pores, and a small-sized pore 131c, as shown in FIG. 4A.

Analysis on the relationship between the structure of the coating film 130 and the electrolyte solution resistance demonstrates that the size of the pores 131 existing in the coating film 130 after baking greatly affects the electrolyte solution resistance.

In other words, if large-sized pores e.g., 131a and 131b etc., are present in the coating layer 130 as shown in FIG. 4A, cracking is easily generated starting from the large-sized pores, e.g., 131a and 131b, etc., in the coating film 130, and the electrolyte solution 5 can contact the current-collecting electrode 120 through the pores to corrode the current-collecting electrode 120.

Therefore, in the photoelectric conversion device 1 manufactured according to one embodiment of the present invention, as shown in FIG. 4B, when the thickness of the coating film 130 is a μm and the maximal length of the pore 131 existing in the coating film 130 is b μm, a condition of b≦0.5a is satisfied.

When the maximal length b of the pore 131 is greater than a value obtained by multiplying a by 0.5 (b>0.5a), the coating film 130 may easily crack or the electrolyte solution 5 may corrode the current-collecting electrode 120 through the pores 131a and 131b.

In one embodiment, to prevent cracking or protect the current-collecting electrode 120 from the penetration of the electrolyte solution 5 through the pores 131a and 131b more effectively, the maximal length b of the pore 131 satisfies a condition of b≦0.3a.

While the maximal length b of the pore 131 is smaller than the thickness of the coating film 130, there is no lower limit for the maximal length b of the pore 131, but the controllable lower limit for the maximal length b of the pore 131 is about b≧0.01a, according to one embodiment.

In one embodiment of this disclosure, in a cross-section of the coating film 130 in parallel or perpendicular to the transparent electrode 110, the maximal length of the pore 131 is the length of a portion of the pore 131 whose cross-section is the largest, that is, the maximal length among the lengths of lines connecting two random points on the perimeter of a cross-section of the pore 131 (for example, when a cross-section of the pore 131 is a circle, the diameter, or when a cross section of the pore 131 is an oval, the major axis).

In one embodiment, with respect to the maximal length b of the pore 131, all the pores 131 existing in the coating film 130 satisfy the condition of b≦0.5a.

This is because, for example, although the average value of the maximal lengths b of the pores 131 existing in the coating film 130 is not greater than 0.5a, if there is any one pore 131 satisfying the condition of b>0.5a, the coating film 130 may crack from the pore 131 with its maximal length b larger than 0.5a.

However, since it is difficult to measure the maximal lengths b of all the pores 131 in the coating film 130, in one embodiment of this disclosure, it is envisioned to be desirable if the above condition is satisfied within the range of about 0.2% of the entire area of a cross-section of the coating film.

The maximal length b of the pore 131 may be measured as follows.

First, a photograph of the pores 131 is taken with a metallurgical microscope, and the shape and size of a portion of the pores 131 are observed by marking the picture image in such a manner that the shape and size of the pores are easily observed. Examples of the method for marking the photographic image in such a manner that the shape and size of the pores are easily observed include: determining a standard; and determining if an observation subject is larger than the standard; and if so, marking the observation subject in black color, or if the observation subject is smaller than the standard, marking the observation subject in white color. However, the present invention is not limited to the above method. Through the method, the distribution of the pores and the shape, size, and number of the pores may be easily determined.

In one embodiment, the image for easily observing the shape and size of the pores may be acquired by automatically measuring the shape and size of the pores 131 with image analysis software, such as Grading Analysis produced by the Keyence company.

With the image analysis software, it is possible to measure the number of pores 131 and the maximal length b and the average size of the pores 131 in the image for easily observing the shape and size of the pores.

In one embodiment, the thickness of the coating film 130 may be measured using a surface shape detecting instrument, such as Dektak150 produced by Veeco company.

As described above, the maximal length b of the pores 131 may be controlled by baking the glass paste composition coating the surface of the current-collecting electrode 120 under suitable set or predetermined conditions.

The baking conditions will be described in more detail below.

### Method of Manufacturing Photoelectric Conversion Device

The structure of the photoelectric conversion device 1 according to one embodiment has been described in detail above.

Hereinafter, the method of manufacturing the photoelectric conversion device 1 according to one embodiment will be described.

### Fabrication of Positive Electrode

First, a transparent conductive oxide (TCO) such as indium tin oxide (ITO), tin oxide (SnO₂), fluorine-doped tin oxide (FTO), antimony-including tin oxide (ITO/ATO), zinc oxide (ZnO₂), or the like is coated on the surface of the substrate 2 by sputtering or the like to provide a transparent electrode 110.

Then a paste composition including a highly conductive metal or alloy such as Ag, Ag/Pd, Cu, Au, Ni, Ti, Co, Cr, Al, or the like, a resin, a solvent, or the like is coated on the transparent electrode 110 to provide a structure having good photoelectric conversion efficiency (for example, a comb tooth shape).

The metal or alloy may be coated by, for example, screen printing, coating using a dispenser, inkjet printing, metal masking, or the like, but it is not limited thereto.

The coated paste composition is dried at a suitable temperature (e.g., about 80° C. to about 200° C.) for removing the solvent and baked at a suitable temperature (e.g., about 400° C. to about 600° C.) for eliminating the resin and baking the metal oxide particulate 31, to provide a current-collecting electrode 120.

A coating film 130 is formed to cover the surface of the current-collecting electrode 120.

For example, the glass frit, a binder resin binding the same, and/or additives, in some embodiments, are dispersed in water and/or an appropriate solvent to provide a glass paste composition.

The obtained glass paste composition is applied to cover the entire surface of the current-collecting electrode 120 except a part that is coupled with the lead line 7.

The glass paste composition may be applied by, for example, screen printing, coating using a dispenser, inkjet printing, or the like.

However, since the coating film 130 is formed of a material having low conductivity, the glass paste composition is applied to sufficiently cover the current electrode 120 with the coating film 130 while minimizing the coated area as much as possible in order to improve the photoelectric conversion efficiency.

Then it is dried at a suitable temperature (e.g., about 80° C. to about 200° C.) for removing the solvent of the coated glass paste composition and baked at a suitable temperature (e.g., more than or equal to the glass softening temperature (Ts) of the glass frit) for eliminating the binder resin and baking the glass frit to provide the coating film 130.

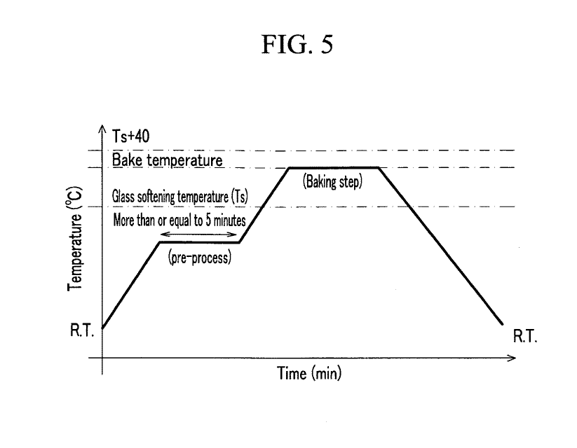

Referring to FIG. 5, a method for baking the glass paste composition in accordance with one embodiment of this disclosure will be described in more detail.

FIG. 5 is a graph showing a baking profile of the glass paste composition according to one embodiment.

As shown in FIG. 5, the method for manufacturing the photoelectric conversion device 1 according to one embodiment of this disclosure includes baking the glass paste composition by increasing the temperature from room temperature to a temperature more than or equal to a softening temperature (Ts) of the glass frit and maintaining the temperature lower than a temperature of Ts+40° C. in order to control the maximal lengths b of the pores 131 to satisfy a condition of b≦0.5a based on the thickness a of the coating film 130.

When the baking temperature of the glass paste composition is higher than or equal to Ts+40° C., since the size of the vapor of the gas generated from the combustion of the binder resin may become too large, the condition of b≦0.5a is difficult to be satisfied. Thus, the coating film 130 may easily crack, and thereby the electrolyte solution 5 may corrode the current-collecting electrode 120 through the pores 131.

Also, since the glass paste composition needs to be baked at a temperature higher than or equal to a temperature for sintering the glass frit, the glass paste composition is baked at a temperature higher than or equal to the softening temperature (Ts) of the glass frit.

In other words, the bake temperature of the glass paste composition according to one embodiment of this disclosure may be equal to or higher than the softening temperature (Ts, ° C.) of the glass frit and lower than a temperature of Ts+40° C.

Also, the time for maintaining the baking temperature at a level equal to or higher than the softening temperature (Ts, ° C.) of the glass frit and lower than the temperature of Ts+40° C. is not limited to specific amounts as long as the binder resin is eliminated and the glass frit is sintered. In one embodiment, the time is from about 5 minutes to about 60 minutes.

According to the method for manufacturing the photoelectric conversion device 1 in accordance with one embodiment of this disclosure, as shown in FIG. 5, a temperature equal to or higher than the vanishing temperature (° C.) of the binder resin and equal to or lower than the softening temperature (Ts, ° C.) may be maintained for more than or equal to about 5 minutes before reaching the baking temperature.

Herein, “maintaining/sustaining” relates to when the temperature higher than or equal to the vanishing temperature (° C.) of the binder resin and lower than or equal to the softening temperature (Ts, ° C.) is maintained for more than or equal to about 5 minutes, the temperature does not have to be a constant temperature, and some variation in temperature may be allowed as long as the variation is within the above temperature range.

As described above, by maintaining/sustaining the temperature equal to or higher than the vanishing temperature (° C.) of the binder resin and lower than or equal to the softening temperature (Ts, ° C.) for more than or equal to about 5 minutes before reaching the baking temperature, it is possible to remove the binder resin or other organic substances included in the glass paste composition by gasifying the binder resin or the organic substances before the temperature reaches the baking temperature of the glass paste composition, that is, before the glass frit is softened and melted.

Therefore, after the glass paste composition is baked, little binder resin or organic substance remains in the glass paste composition, and thus, it is possible to suppress the generation of pores 131 having a large maximal length b.

Here, “vanishing temperature (° C.) of the binder” refers to a temperature where about 95% or more of weight is eliminated when thermogravimetry-differential thermal analysis (TG-DTA) is performed under an air atmosphere.

After the coating film 130 is fabricated, the effective surface area of the electrode substrate 10 (region capable of photoelectric conversion) is treated with a metal (e.g., platinum, gold, silver, copper, aluminum, rhodium, indium, or the like), a metal oxide (e.g., indium tin oxide (ITO), tin oxide (including one doped with fluorine), zinc oxide, or the like), a conductive carbon material or a conductive organic material, or the like, by sputtering or other suitable processes, so as to fabricate the counter electrode 4. Accordingly, a positive electrode is fabricated.

### Fabrication of Negative Electrode

First, an electrode substrate 10 including a transparent electrode 110, a current-collecting electrode 120, and a coating film 130 is formed on the surface of a substrate 2, in a manner substantially the same as in the positive electrode.

Then metal oxide particulate 31 such as TiO₂ (e.g., having a particle diameter of nanometer unit) and an organic binder for binding the same are dispersed in water and/or an organic solvent to provide a paste composition.

The obtained paste composition is coated on the whole effective area of the surface of the electrode substrate 10 (region capable of photoelectric conversion).

The paste composition may be coated by, for example, screen printing, squeegee coating, dispenser coating, spin coating, dip coating, spray-coating, die coating, inkjet printing, or the like.

The coated paste composition is dried at a suitable temperature (e.g., about 80° C. to about 200° C.) for removing the solvent and baked at a suitable temperature (e.g., about 400° C. to about 600° C.) for eliminating the binder resin and baking the metal oxide particulate 31, to provide a metal oxide semiconductor layer.

The substrate 2 and the electrode substrate 10 formed with the metal oxide semiconductor layer are dipped in a solution in which a sensitizing dye 33 is dissolved (for example, an ethanol solution including ruthenium complex-based dyes) for several hours to bind the sensitizing dye 33 with the surface of the metal oxide particulate 31 using affinity of the surface of the metal oxide particulate 31 with the connecting group 35 of the sensitizing dye 33.

Then the metal oxide semiconductor layer bound with the sensitizing dye 33 is dried at a suitable temperature for removing the solvent (e.g., about 40° C. to about 100° C.) to provide a photoelectrode 3. Accordingly, a negative electrode is fabricated.

However, a method of binding the sensitizing dye 33 on the surface of the metal oxide particulate 31 is not limited, to the above method.

### Connection of Positive Electrode and Negative Electrode

The obtained positive electrode is placed to face the negative electrode, and spacers (for example, made of an ionomer resin such as HIMILAN (trade name) produced by Mitsui DuPontPolychemical K.K, or the like) are placed at the connection part around each substrate 2, and the positive electrode and the negative electrode are thermally bound at a suitable temperature (e.g., about 120° C.).

The electrolyte solution (for example, an acetonitrile electrolyte solution dissolved with LiI and I₂) is injected through an injection hole and widely distributed in the entire cell to provide a photoelectric conversion device 1.

In some embodiments, a plurality of photoelectric conversion devices 1 may be coupled together.

For example, a plurality of photoelectric conversion devices 1 are coupled in series to increase the overall generated voltage.

### Second Embodiment

A photoelectric conversion device according to another embodiment of this disclosure has substantially the same structure as the photoelectric conversion device according to the previous embodiment, except that the maximal length of a pore existing in the coating film is defined by the maximal length of the pore itself, instead of defining the maximal length of the pore based on the thickness of the coating film.

According to one embodiment, the maximal length of a pore is shorter than or equal to about 10 μm.

In one embodiment, when the maximal length of the pore exceeds about 10 μm, the coating film is easily crack and/or an electrolyte solution corrodes a current-collecting electrode through the pore.

Also, in one embodiment, the maximal length of the pore is shorter than or equal to about 10 μm in order to improve the conversion efficiency of the photoelectric conversion device as well.

In a photoelectric conversion device, if a cell gap, that is, the gap between an anode and a cathode, is too large, the conversion efficiency of the photoelectric conversion device is deteriorated.

A relationship between a cell gap and the conversion efficiency is exemplarily described below.

Exemplary photoelectric conversion cells were manufactured by using the coating films (see Table 4) of the following example according to the same methods as used in the above example.

Herein, the cell gap is varied, and the conversion efficiency of the photoelectric conversion cell with each cell gap is measured according to the same method as the above example.

The measurement results are presented in the following Table 1.

TABLE 1

| Cell Gap (μm) | Conversion Efficiency (%) |
|---|---|
| 30 | 7.23 |
| 60 | 7.16 |
| 90 | 6.67 |
| 120 | 6.02 |
| 150 | 5.29 |

Referring to Table 1, as the cell gap becomes wider, the conversion efficiency is deteriorated.

According to another embodiment of this disclosure, since the cell gap becomes wider as the coating film becomes thicker, the thickness of the coating film should be as small as possible.

Also, if the maximal length of a pore is too long compared with the thickness of the coating film, the coating film may easily crack.

Therefore, to improve the conversion efficiency, the maximal length of a pore should be as short as possible. In one embodiment, the maximal length of a pore is shorter than or equal to about 10 μm. Since it is better as the maximal length of a pore is shorter, there is no particular lower limit for the maximal length of a pore. In one embodiment, the lower limit of the maximal length of a pore that may be controllable is about 0.2 μm.

Here, measurement method, and control method of the maximal length of a pore are as described in the previous embodiments of this disclosure.

Since the other structures of the photoelectric conversion device and the manufacturing method of the photoelectric conversion device are the same as described in the previous embodiment of this disclosure, further description of them will not be provided again.

### Example

The following example illustrates the present invention in more detail.

In the example, durability (electrolyte solution resistance) of a coating film to an electrolyte solution and performance (photoelectric conversion efficiency) of a dye sensitized solar cell are analyzed.

### Analysis of Durability to Electrolyte Solution

First, durability of the coating film to the electrolyte solution is analyzed.

### Fabrication of Current-Collecting Electrode

An Ag paste (produced by Tanaka Kikinzoku, Type MH1085) is patterned on a glass substrate (produced by Asahi Glass Co., Ltd., Type U-TCO) including a fluorine-doped tin oxide layer (transparent electrode layer) by screen printing to provide a stripe having a thickness of about 10 μm and a width of about 500 μm, so as to provide a current-collecting electrode.

### Preparation of Glass Paste Composition

A glass paste composition is prepared by mixing 5 g of ethyl cellulose binder resin (vanishing temperature 400° C.), 60 g of glass frit (B₂O₃—SiO₂—Bi₂O₃-based glass frit, glass softening temperature (Ts) of 475° C.), 30 g of terpineol (produced by Kanto Chemical Co., Inc.), and 5 g of butylcarbitol acetate (produced by Kanto Chemical Co., Inc.) and sufficiently dispersing the mixture with a 3-roller mixer.

### Formation of Coating Film

The obtained glass paste composition is completely coated on a current-collecting electrode and is patterned by screen printing to provide a stripe having a width of 1000 μm.

Then the resulting current-collecting electrode is dried in an oven at about 150° C. to remove the solvent from the glass paste composition, and is baked for about 30 minutes under the air atmosphere to eliminate the binder resin, so as to provide a coating film.

The baking is performed at each temperature (490° C., 500° C., 510° C., and 520° C.) as shown in the following Table 2.

Also, the total number of pores existing in the formed coating film, the maximum value of the maximal lengths b of the pores, and the average value of the maximal lengths b of the pores are measured.

As to the maximal lengths b of the pores, values are automatically measured by using image analysis software Grading Analysis (produced by Keyence company), and the maximal lengths b of the pores are measured at 5 regions each having an area of about 160 μm×120 μm in an obtained image.

The following Table 2 shows the baking temperature of each coating film, temperature ascending speed to each baking temperature, the maximum value of the maximal lengths b of the pores, the total number of pores, and the average value of the maximal lengths b of the pores.

Here, the thickness of the coating film is about 20 μm in all examples.

In the examples, the baking temperature refers to the highest temperature that a glass paste composition has reached during a baking process, and the temperature ascending speed refers to the speed of temperature increase to the baking temperature after the temperature reaches the glass softening temperature of the glass frit.

TABLE 2

| Baking temperature | Number | Maximum value | Average value of |
|---|---|---|---|
| (° C.) | of pores | of b (μm) | b (μm) |
| 490 | 1932 | 10.0 | 0.99 |
| 500 | 1750 | 9.4 | 1.0 |
| 510 | 1567 | 9.9 | 0.99 |
| 520 | 1337 | 12.3 | 0.93 |

The temperature ascending speed of Table 2 is about 10° C./min.

Referring to Table 2, if the conditions (equal to or higher than the glass softening temperature (Ts) and equal to or lower than Ts+40° C.) of the baking temperature specified in the above described embodiments of this disclosure are satisfied (for example, baking temperatures of 490° C., 500° C., and 510° C.), the maximum value of the maximal lengths b of the pores becomes smaller than or equal to about 10 μm, and thus, the condition of the maximal length b specified in the above described embodiments is satisfied.

However, when the baking temperature is beyond the temperature of Ts+40° C. (e.g., a comparative example where baking temperature is 520° C.), the maximum value of the maximal lengths b of the pores exceeds about 10 μm, and the condition of the maximal length b of a pore specified in the above described embodiments of this disclosure is not satisfied.

### Fabrication of Test Cell

A test cell is fabricated by thermally compressing the glass substrate with a current-collecting electrode formed thereon, which is obtained through the above described method, with an FTO glass substrate by using a hot-melting resin called HIMILAN (having a thickness of about 120 μm), injecting an electrolyte solution through an electrolyte injection opening, and then sealing the electrolyte injection opening with HIMILAN and a glass cover.

### Analysis on Electrolyte Solution Resistance

The fabricated test cell is allowed to stand at a temperature of about 85° C. for about 1000 hours, and then the shape and state of the current-collecting electrode and the coating film are observed.

As a result, damage is not observed with bare eyes in the test cell fabricated according to the example.

### Effect of Baking Temperature on the Generation of Pores

The effect of the bake temperature on the generation of pores in a coating film is studied.

In other words, the glass paste composition obtained through the above-described method is applied to a glass substrate (produced by Asahi Glass Co., Ltd., type U-TCO) having a fluorine-doped tin oxide layer (transparent electrode layer), the glass paste composition is dried to remove solvent from the glass paste composition in an oven set to a temperature of about 150° C., and then the resultant glass substrate coated with the glass paste composition without solvent remaining is baked in the air atmosphere.

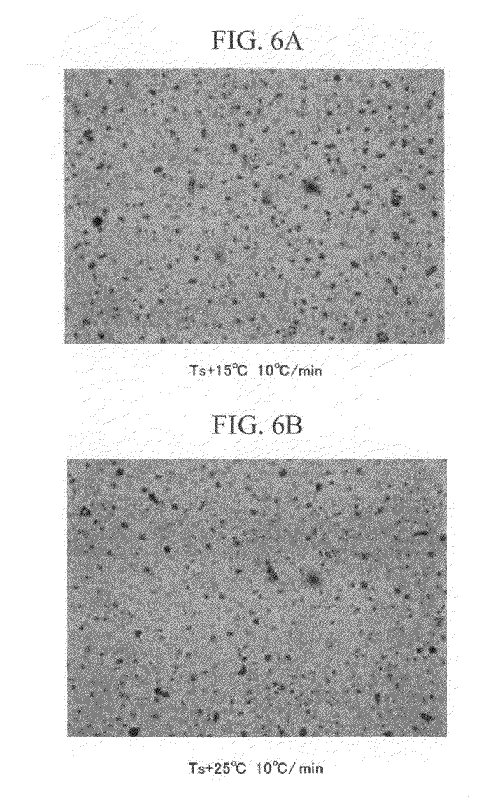

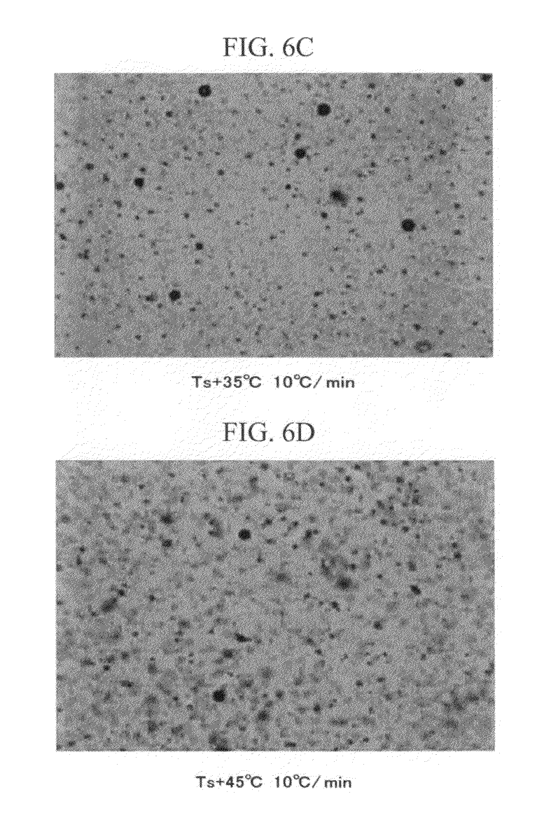

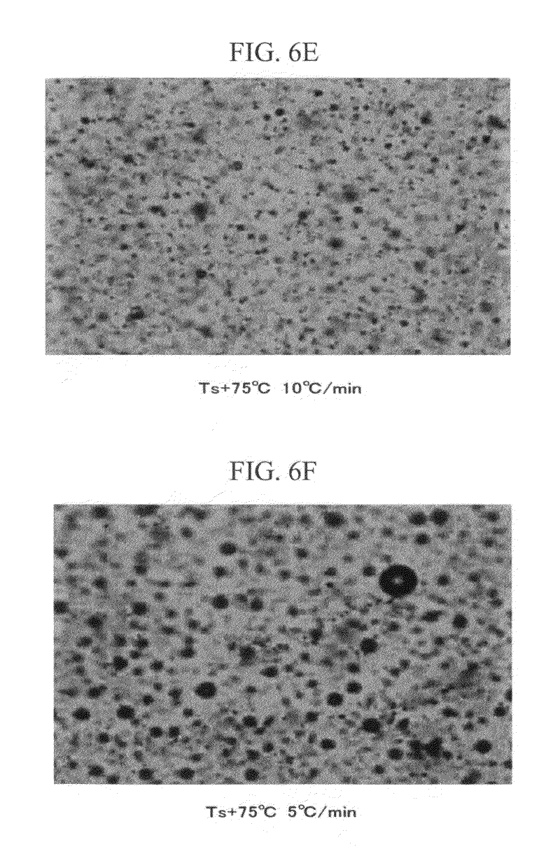

Referring to FIGS. 6A to 6F, the baking conditions are as follows. The baking temperature is varied from a temperature of Ts+15° C. to a temperature of Ts+75° C., the temperature ascending speed is set to about 10° C./min (about 5° C./min for FIG. 6F), and the baking time is about 20 minutes.

FIGS. 6A to 6F are microscope photographs exemplarily showing states of coating films after being baked.

As a result, it may be seen that the coating films of FIGS. 6A to 6C that satisfy the condition of the bake temperature (lower than a temperature of Ts+40° C.) in the method for manufacturing a photoelectric conversion device in accordance with one embodiment have small pores (see the dark portion of the images) and have a small number of pores.

However, the coating films of FIGS. 6D to 6F, which are obtained at the baking temperature of higher than or equal to about Ts+40° C., have larger pores.

### Effect of Pre-Process on the Generation of Pores

Hereinafter, an effect of a pre-process (a process of maintaining/sustaining temperature before baking) on the generation of pores in a coating film is studied.

In one embodiment, a glass paste composition prepared as described above is applied to a glass substrate (e.g., a glass substrate produced by Asahi Glass Co., Ltd., type U-TCO) having a fluorine-doped tin oxide layer (transparent electrode layer), and the glass paste composition is dried to remove its solvent in an oven set to about 150° C., and baked in the air atmosphere.

The baking conditions are as follows. The baking temperature is about 500° C., the time for maintaining/sustaining the baking temperature is about 20 minutes, and the temperature ascending speed is about 10° C./min.

Here, for one of two samples baked under the same conditions, a pre-process of maintaining the temperature at about 420° C. for about 30 minutes is applied before a baking process, and for the other sample, the pre-process is not applied.

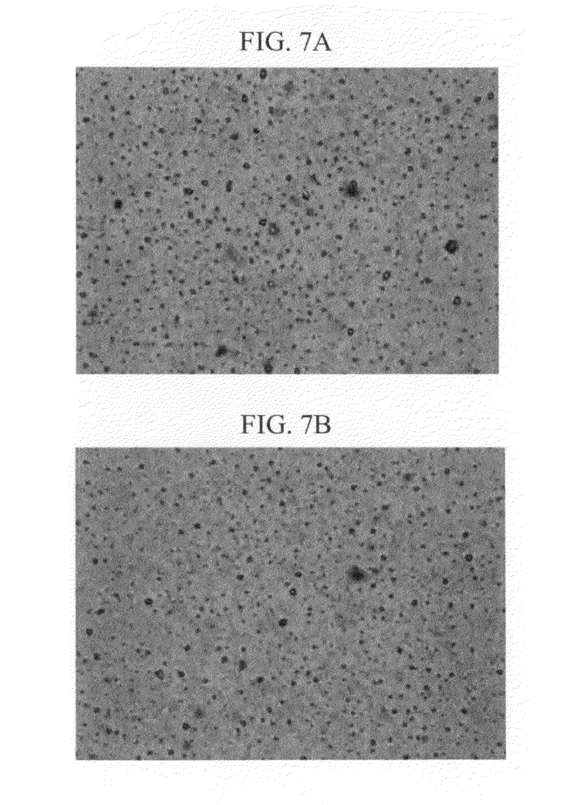

The results are as presented in FIGS. 7A and 7B.

FIG. 7A is a microscope photograph exemplarily showing a state of a baked coating film with no pre-process applied.

FIG. 7B is a microscope photograph exemplarily showing a state of a baked coating film when a pre-process is applied.

TABLE 3

| | Number | Maximum | Average |
|---|---|---|---|
| | of Pores | Value of b | Value of b |
| Pre-processed | (EA) | (μm) | (μm) |
| No | 1783 | 9.5 | 1.19 |
| Yes | 1688 | 9.4 | 1.08 |

As a result, the coating film of FIG. 7B that has gone through the pre-process has smaller pores (i.e., dark portions in the image) and a smaller number of pores than the coating film of FIG. 7A that does not go through the pre-process.

In other words, in the coating film shown in FIG. 7B, the number of pores is decreased due to the pre-process, and at the same time, the generation of pores with larger maximal lengths b is suppressed or reduced. Therefore, as shown in Table 3, the average value of the maximal lengths b of the pores becomes considerably smaller in the coating film of FIG. 7B that is obtained after going through the pre-process.

### Example of Corroded Current-Collecting Electrode Due to Pores

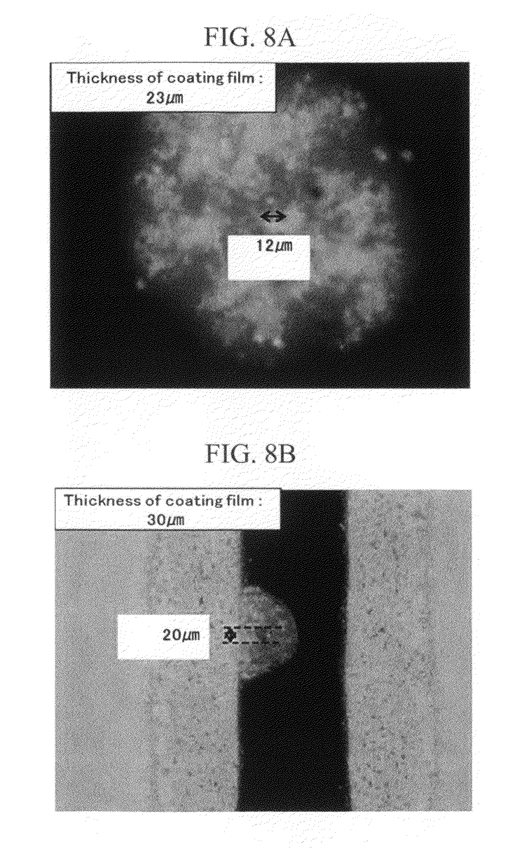

FIGS. 8A and 8B show examples of cracking of coating film and a corroded current-collecting electrode due to overlarge pore size.

FIGS. 8A and 8B are microscope photographs exemplarily showing states of corroded current-collecting electrodes.

As shown in FIGS. 8A and 8B, when the maximal lengths b of the pores satisfy a condition of b>0.5a based on the thickness a of the coating film, a current-collecting electrode is corroded by an electrolyte solution due to the existence of a large pore in the middle of the coating film (e.g., the transparent portion (light portion) in FIGS. 8A and 8B is the corroded portion of the current-collecting electrode).

### Performance Analysis of Dye Sensitized Solar Cell

Hereinafter, the performance of a dye sensitized solar cell is analyzed.

### Transparent Electrode

In both the example and the comparative example, a glass substrate (e.g., a glass substrate produced by Asahi Glass Co., Ltd., type U-TCO) having a fluorine-doped tin oxide layer (transparent electrode layer) as a transparent electrode is used.

### Formation of Current-Collecting Electrode

A current-collecting electrode is formed by patterning an Ag paste (e.g., an Ag paste produced by Tanaka Kikinzoku, MH1085) on the glass substrate in a thickness of about 10 μm and a width of about 500 μm in a stripe form through screen printing.

Here, the pitch between current-collecting electrodes is about 7000 μm.

### Formation of Coating Film

A glass paste composition is prepared by mixing 5 g of an ethyl cellulose resin (which has a vanishing temperature of 400° C.), 60 g of glass frit (e.g., B₂O₃—SiO₂—Bi₂O₃-based glass frit, glass softening temperature (Ts) of 480° C.), 30 g of terpineol (e.g., a terpineol produced by Kanto Chemical Co., Inc.), and 5 g of butylcarbitol acetate (e.g., a butylcarbitol acetate produced by Kanto Chemical Co., Inc.), and sufficiently dispersing the mixture with a 3-roller mixer.

Electrode substrates including coating films of the example and the comparative example of this disclosure are fabricated by using the prepared glass paste composition under the following baking conditions.

The baking conditions of the example include a baking temperature of about 500° C. and a baking temperature maintenance/sustaining time of about 20 minutes after a pre-process of maintaining the temperature at about 420° C. for about 30 minutes.

The baking conditions of the comparative example do not include the pre-process, the baking temperature is about 550° C., and the baking temperature maintenance/sustaining time is about 20 minutes.

The coating films have a thickness of about 20 μm for both the example and the comparative example.

For the coating films as described above, the thickness a of the coating film and the maximal length b of a pore are compared (b/a), and the number of pores is measured for a number of (b/a) ranges.

The maximal lengths b may be automatically measured with image analysis software, such as Grading Analysis (produced by Keyence company).

Here, the maximal lengths b of pores are measured in a region of 10 mm×50 mm of an image.

The measurement results are as shown in the following Table 4 (example) and Table 5 (comparative example).

Here, the “Number of Erroneous Spots” in Tables 4 and 5 refers to the number of erroneous spots damaged on the coating film of a current-collecting electrode by a crack generated due to pores having a large maximal length b.

TABLE 4

| | Number of Pores | Number of Erroneous |
|---|---|---|
| b/a | (EA) | Spots (EA) |
| b/a ≦ 0.1 | 872,930 | 0 |
| 0.1 < b/a ≦ 0.2 | 985 | 0 |
| 0.2 < b/a ≦ 0.3 | 219 | 0 |
| 0.3 < b/a ≦ 0.4 | 38 | 0 |
| 0.4 < b/a ≦ 0.5 | 4 | 0 |
| 0.5 < b/a ≦ 0.6 | 0 | — |
| 0.6 < b/a ≦ 0.7 | 0 | — |
| 0.7 < b/a ≦ 0.8 | 0 | — |
| 0.8 < b/a ≦ 0.9 | 0 | — |
| 0.9 < b/a ≦ 1.0 | 0 | — |

TABLE 5

| | Number of | Number of Erroneous |
|---|---|---|
| b/a | Pores (EA) | Spots (EA) |
| b/a ≦ 0.1 | 604,965 | 0 |
| 0.1 < b/a ≦ 0.2 | 5406 | 0 |
| 0.2 < b/a ≦ 0.3 | 1395 | 0 |
| 0.3 < b/a ≦ 0.4 | 476 | 0 |
| 0.4 < b/a ≦ 0.5 | 158 | 0 |
| 0.5 < b/a ≦ 0.6 | 35 | 7 |
| 0.6 < b/a ≦ 0.7 | 11 | 6 |
| 0.7 < b/a ≦ 0.8 | 3 | 3 |
| 0.8 < b/a ≦ 0.9 | 1 | 1 |
| 0.9 < b/a ≦ 1.0 | 0 | — |

As shown in Tables 4 and 5, the coating film according to the example satisfies the condition of b/a≦0.5 (b≦0.5a) for all pores in the measurement ranges, and erroneous spots are not generated.

On the other hand, the coating film according to the comparative example includes large pores having a maximal length b of b/a>0.5, and with the large pores, the coating film includes some erroneous spots.

### Counter Electrode

In both the example and the comparative example, a counter electrode is fabricated by forming a current-collecting electrode and a coating film on an electroconductive layer of a glass substrate (e.g., a glass substrate produced by Asahi Glass Co., Ltd., type U-TCO) having a fluorine-doped tin oxide layer and stacking a platinum layer (platinum electrode layer) having a thickness of about 150 nm through a sputtering method. Also, a method for forming the current-collecting electrode and the coating film is as described above.

### Preparation of Paste Composition for Photoelectrode (Titanium Oxide Electrode)

Subsequently, a paste composition for a photoelectrode is fabricated according to one embodiment.

For each of the example and the comparative example, a mixture of 3 g of titanium oxide particulates (e.g., titanium oxide particulates produced by Japan Aerosil company, P-25), 0.2 g of acetyl acetone, and 0.3 g of a surfactant (e.g., a surfactant produced by Waco Pure Chemical Industry, polyoxyethylene octylphenylether) along with 7.0 g of terpineol is dispersed for about 12 hours through a bead mill treatment.

A paste composition is prepared by adding 1.0 g of an ethyl cellulose resin as a binder resin to the acquired dispersion solution.

The viscosity at the shear rate of about 10 sec⁻¹ of the paste composition may be a sufficient viscosity for screen printing.

### Fabrication of Titanium Oxide Electrode

Subsequently, a titanium oxide electrode including titanium oxide particulates is fabricated.

For each of the example and the comparative example, a titanium oxide electrode including a titanium oxide porous layer having a film thickness of about 10 μm and an effective area of about 100 cm² is fabricated by applying the above-prepared paste composition to an electroconductive surface of an electrode substrate with a coating film through screen printing and sintering it in an oven set to a temperature of about 450° C. for about 1 hour.

### Adsorption of Sensitizing Dye

Then, the obtained titanium oxide electrode is adsorbed with a sensitizing dye in accordance with the following method.

A sensitizing dye (e.g., N719 produced by Solaronix) for photoelectric conversion is dissolved in ethanol (concentration: 0.6 mmol/L) to provide a dye solution. Then the titanium oxide electrode is dipped in the dye solution and allowed to stand at room temperature for 24 hours.

The dyed surface of titanium oxide electrode is washed with ethanol and dipped in a 2 mol % alcohol solution of 4-t-butyl pyridine for 30 minutes and dried at room temperature to provide a photoelectrode including a titanium oxide porous layer adsorbed with a sensitizing dye.

### Preparation of Electrolyte Solution

Then the electrolyte solution having the following composition is prepared.

In one embodiment, a solvent for dissolving an electrolyte is methoxy acetonitrile.

LiI: 0.1 M

I₂: 0.05 M

4-t-butyl pyridine: 0.5 M

propyl-2,3-dimethylimidazolium iodide: 0.6 M

### Assembling of Photoelectric Conversion Cells

Then, using the obtained photoelectrode and counter electrode, a sample of a photoelectric conversion cell (photoelectric conversion device) shown in FIG. 1 is assembled.

In one embodiment, an electrolyte solution layer is formed by fixing the photoelectrode fabricated as described above and the counter electrode fabricated as described above with a resin film spacer (e.g., a resin film spacer produced by Mitsui DuPont Polychemical, HIMILAN film (which has a thickness of 120 μm), interposed between them, and injecting the electrolyte solution into the space.

The glass substrate is connected to each line for measuring conversion efficiency.

### Measurement of Conversion Efficiency

The conversion efficiencies of the photoelectric conversion cells obtained from the example and the comparative example are measured based on the following method.

In one embodiment, a solar simulator (e.g., Solar Simulator produced by ORIEL) is assembled with an air mass filter, and a light source for measurement is adjusted to provide a light amount of 100 mW/cm². The sample of the photoelectric cell is irradiated and measured for I-V curve characteristics using a source meter (e.g., Keithley model 2400 source meter).

The conversion efficiency η(%) is calculated according to the following Equation 1 using an open voltage (Voc), a short-cut current (Isc), and a fill factor (ff) from the I-V curve characteristics.

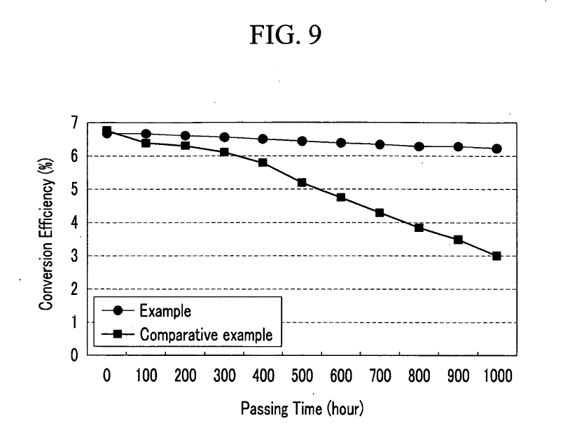

FIG. 9 shows the changes in the conversion efficiency values according to time variation.

FIG. 9 is a graph showing relationships between the conversion efficiencies (η) of photoelectric conversion cells according to the example and the comparative example and time.

$$η ( \% ) = \frac{Voc ( V ) \times Isc ( mA ) \times ff}{100 ( mW / {cm}^{2} ) \times 100 {cm}^{2}} \times 100 \qquad Equation 1$$

As illustrated in FIG. 9, both of the photoelectric conversion cells of the example and the comparative example have high initial photoelectric conversion efficiencies of over 6%. For example, at time 0, the photoelectric conversion cell of the example has a conversion efficiency of 6.67%, and the photoelectric conversion cell of the comparative example has a conversion efficiency of 6.75%.

However, while the conversion efficiency of the photoelectric conversion cell of the comparative example is remarkably deteriorated as time passes by, the photoelectric conversion cell of the example maintains the high conversion efficiency.

Since the photoelectric conversion cell of the comparative example has many large pores whose maximal length is large, it is considered that when the coating film cracks, the current-collecting electrode is corroded by the electrolyte solution such that the conversion efficiency is deteriorated.

Here, since the maximal lengths of all pores existing in the coating film is less than about half the thickness of the coating film in the photoelectric conversion cell of the example, the generation of cracks in the coating film is suppressed or reduced and thus the current-collecting electrode is not corroded. Therefore, the conversion efficiency is substantially maintained.

It may be seen from the above results that when a coating film coating a current-collecting electrode is formed under the range of conditions according to the above described embodiments of this disclosure, the sizes of the pores existing in the coating film satisfy the condition b≦0.5a described above.

As a result, the coating film is protected from cracking, and since the current-collecting electrode does not contact the electrolyte solution, the current-collecting electrode is protected from being corroded.

Therefore, a photoelectric conversion device including a dye sensitized solar cell fabricated using the electrode substrate according to an embodiment of the present invention may have high efficiency, long lifespan, and high durability.

Although the embodiments are described in detail with reference to the attached drawings, this disclosure is not limited thereto.

For example, according to one embodiment of this disclosure, the inorganic semiconductor particulate 31 has a photoelectric conversion function and is sensitized by treating its surface with a sensitizing dye, but the inorganic semiconductor particulate is not limited to the metal oxide particulate 31 but may include, for example, an inorganic semiconductor particulate that is not a metal oxide.

The inorganic semiconductor particulate may include, for example, silicon, germanium, a Group III-Group V semiconductor, a metal chalcogenide, or the like, which is not a metal oxide.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and their equivalents.

What is claimed is:

1. An electrode substrate for a photoelectric conversion device comprising
a transparent conductive substrate;
a current-collecting electrode on the transparent conductive substrate; and
a coating film coating a surface of the current-collecting electrode,
wherein when a thickness of the coating film is a and a maximal length of a pore in the coating film is b, a condition of b≦0.5a is satisfied.

2. The electrode substrate of claim 1, wherein the coating film is formed by coating the surface of the current-collecting electrode with a glass paste composition and baking the current-collecting electrode coated with the glass paste composition.

3. An electrode substrate for a photoelectric conversion device comprising:
a transparent conductive substrate;
a current-collecting electrode on the transparent conductive substrate; and
a coating film coating a surface of the current-collecting electrode,
wherein a maximal length of a pore in the coating film is not larger than about 10 μm.

4. The electrode substrate of claim 3, wherein the coating film is formed by coating the surface of the current-collecting electrode with a glass paste composition and baking the current-collecting electrode coated with the glass paste composition.

5. A photoelectric conversion device comprising:
an electrode substrate comprising a current-collecting electrode on a transparent conductive substrate and a coating film coating a surface of the current-collecting electrode,
wherein, when a thickness of the coating film is a and a maximal length of a pore in the coating film is b, a condition of b≦0.5a is satisfied.

6. The photoelectric conversion device of claim 5, wherein the coating film is formed by coating the surface of the current-collecting electrode with a glass paste composition and baking the current-collecting electrode coated with the glass paste composition.

7. The photoelectric conversion device of claim 5, wherein the photoelectric conversion device is a dye sensitized solar cell.

8. A photoelectric conversion device comprising:
an electrode substrate comprising a current-collecting electrode on a transparent conductive substrate and a coating film coating a surface of the current-collecting electrode,
wherein the coating film is formed by coating the surface of the current-collecting electrode with a glass paste composition and baking the current-collecting electrode coated with the glass paste composition, and
wherein a maximal length of a pore in the coating film is not larger than about 10 μm.

9. The photoelectric conversion device of claim 8, wherein the photoelectric conversion device is a dye sensitized solar cell.

10. A method for fabricating an electrode substrate, the method comprising:
forming a coating film coating a surface of a current-collecting electrode on a transparent conductive substrate with a glass paste composition comprising a glass frit, a binder resin, and an organic solvent; and
baking the glass paste composition at a baking temperature equal to or higher than a softening temperature (Ts) of the glass frit and lower than a temperature of about 40° C. higher than the softening temperature (Ts+40° C.).

11. The method of claim 10, further comprising:
maintaining the glass paste composition at a temperature not lower than a vanishing temperature of the binder resin and not higher than the softening temperature (Ts) of the glass frit for more than or equal to about 5 minutes, before reaching the baking temperature.

12. The method of claim 10, wherein when a thickness of the coating film is a and a maximal length of a pore in the coating film is b, a condition of b≦0.5a is satisfied.

13. The method of claim 10, wherein a maximal length of a pore in the coating film is not larger than about 10 μm.
